(19) United States
(12) Patent Application Publication
(10) Pub. No.: US 2014/0202382 A1
(43) Pub. Date: Jul. 24, 2014

(54) DEPOSITION APPARATUS

(71) Applicant: ASM IP Holding B.V., Almere (NL)

(72) Inventors: Young-Jae KIM, Cheonan-si (KR); Ki Jong Kim, Daejeon (KR); Dong-Rak Jung, Cheonam-si (KR); Hak Yong Kwon, Osan-si (KR); Seung Woo Choi, Cheonan-si (KR)

(73) Assignee: ASM IP Holding B.V., Almere (NL)

(21) Appl. No.: 14/157,626

(22) Filed: Jan. 17, 2014

(30) Foreign Application Priority Data
Jan. 21, 2013 (KR) 10-2013-0006678

(51) Int. Cl. C23C 16/458

(52) U.S. Cl. CPC C23C 16/458
USPC 118/500

(57) ABSTRACT

A deposition apparatus is provided to eliminate unnecessary empty spaces that may form between a substrate and a substrate supporting pin, which may be formed within a substrate supporting pin hole, by covering the substrate supporting pin, inserted into the substrate supporting pin hole formed in the substrate support, by a substrate supporting pin cover loaded on the substrate support. Accordingly, the temperature under the substrate can be maintained constant, and generation of parasitic plasma or contaminating particles can be avoided.

### CROSS-REFERENCE TO RELATED APPLICATION

This application claims priority to and the benefit of Korean Patent Application No. 10-2013-0006678 filed in the Korean Intellectual Property Office on Jan. 21, 2013, the entire contents of which are incorporated herein by reference.

### BACKGROUND OF THE INVENTION

(a) Field of the Invention

The present invention relates to a deposition apparatus.

(b) Description of the Related Art

A substrate supporting pin (or substrate lift pin) is used in a deposition apparatus for depositing a film on a silicon substrate, in order to load or unload the substrate before and after the process.

The substrate supporting pin is inserted into a substrate support where the substrate is loaded, and moves vertically to load or unload the substrate. When the substrate supporting pin moves down to cause the substrate to be loaded on the support substrate, an empty space is formed between the substrate and the substrate supporting pin, within a supporting pinhole into which the substrate supporting pin is inserted.

As such empty space has lower thermal conductivity compared to other areas supporting the substrate by the substrate support, the uniformity of a thin film may be declined due to a temperature difference between the empty space and the other areas supporting the substrate when the thin film is formed on the substrate. Moreover, in a deposition process using plasma, parasitic plasma may be generated in this empty space, and this may form an unnecessary thin film on the opposite side of the substrate surface where the process is performed. Further, process gas may move into the empty space and act as contaminating particles, thus lowering the quality of the thin film.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a deposition apparatus for loading and unloading a substrate using a substrate supporting pin, which is able to maintain the temperature under the substrate constant and prevent generation of parasitic plasma or contaminating particles by eliminating unnecessary empty spaces within a supporting pin hole formed in the substrate support.

An exemplary embodiment of the present invention provides a deposition apparatus including: a substrate support; a substrate supporting pin inserted into a hole formed in the substrate support; a supporting plate supporting the substrate supporting pin; and a supporting pin cover arranged on top of the substrate supporting pin within the hole of the substrate support.

The upper surface of the supporting pin cover may be almost the same height as the upper surface of the substrate support.

The upper surface of the supporting pin cover may have almost the same cross-sectional area as the hole.

The supporting pin cover may further include a lower body located under the upper surface of the supporting pin cover and having an insertion hole, and the insertion hole may have almost the same cross-sectional area as the supporting pin.

The upper surface of the supporting pin may be concave or convex, and the insertion hole of the supporting pin cover may be convex or concave so as to engage with a concavity or convexity on the upper surface of the supporting pin.

A coupling slot having a smaller cross-sectional area than the supporting pin may be formed in the upper surface of the supporting pin, and a coupling projection having almost the same cross-sectional area as the coupling slot may be formed on the lower surface of the supporting pin cover.

A coupling projection having a smaller cross-sectional area than the supporting pin may be formed on the upper surface of the supporting pin, and a coupling slot having almost the same cross-sectional area as the coupling projection may be formed in the lower surface of the supporting pin cover. The supporting pin cover may further include a lower surface having almost the same cross-sectional area as the hole.

A plurality of through holes may be formed in the upper surface of the supporting pin cover.

The substrate support may further include a projecting portion in the supporting pin hole, and the projecting portion may take the form of a plate-like circle surrounding the supporting pin cover in a circle or the form of a plurality of protuberances arranged around the supporting pin cover.

A deposition apparatus according to an exemplary embodiment of the present invention can eliminate unnecessary empty spaces between a substrate and a substrate supporting pin, which may be formed within a supporting pin hole, by covering the substrate supporting pin, inserted into the supporting pin hole formed in the substrate support, by a substrate supporting pin cover loaded on the substrate support. Accordingly, the temperature under the substrate can be maintained constant, and generation of parasitic plasma or contaminating particles can be avoided.

### BRIEF DESCRIPTION OF THE DRAWINGS

FIG. 1 is a cross-sectional view showing a deposition apparatus according to an exemplary embodiment of the present invention.

FIG. 2 is a cross-sectional view showing part of a deposition apparatus according to one exemplary embodiment of the present invention.

FIG. 3 and FIG. 4 are views showing a substrate supporting pin cover of a deposition apparatus according to an exemplary embodiment of the present invention.

FIG. 5 and FIG. 6 are views showing a substrate supporting pin cover of a deposition apparatus according to another exemplary embodiment of the present invention.

FIG. 7 to FIG. 12 are views showing examples of a substrate supporting pin and a substrate supporting pin cover of a deposition apparatus according to exemplary embodiments of the present invention.

### DETAILED DESCRIPTION OF THE EMBODIMENTS

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

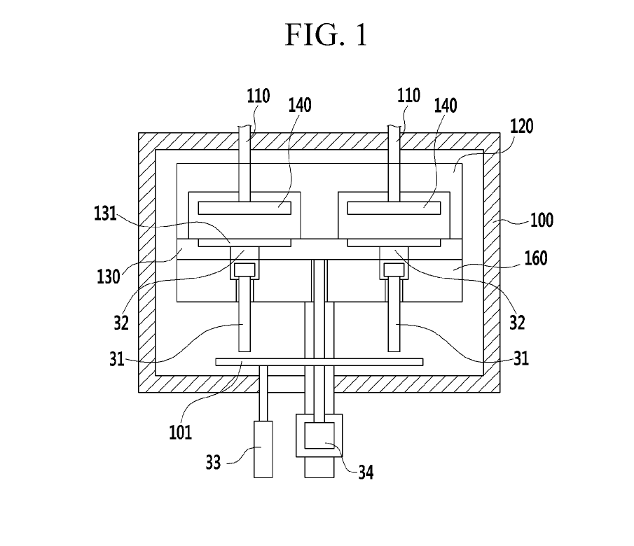

First, a deposition apparatus according to an exemplary embodiment of the present invention will be described with reference to FIG. 1. FIG. 1 is a cross-sectional view showing a deposition apparatus according to an exemplary embodiment of the present invention.

Referring to FIG. 1, the deposition apparatus according to the exemplary embodiment of the present invention includes an outer wall 100, a plurality of gas passage pipes 110, a reaction chamber wall 120, a substrate support 130, a reaction chamber plate 140 defining a reaction space together with the substrate support 130, a heating plate 160 for heating the substrate support 130, a substrate supporting pin 31 inserted into a hole formed in the substrate support 130 and the heating plate 160, a substrate supporting pin cover 32 located on top of the substrate supporting pin 31, and substrate support actuators 33 and 34.

Each of the constituent elements will be explained in more detail. A substrate 131 for deposition is arranged on top of the substrate support 130, and the heating plate 160 is arranged under the substrate support 130. The heating plate 160 serves to increase the substrate temperature up to a level required for a process, and may be omitted.

The substrate support actuator for actuating the substrate support 130 to load and unload the substrate 131 includes a vertical actuator 33 for controlling vertical movement of the substrate supporting pin 31, which is inserted into the hole formed in the substrate support 130 and supports the substrate, the substrate supporting pin cover 32, and the substrate support 130, and a rotational actuator 34 for controlling rotation of the substrate support 130. A variety of means, such as a pneumatic cylinder, for controlling the vertical movement of the substrate support 130 may be used as the vertical actuator 33. The substrate supporting pin 31 can be supported by a supporting plate 101 which is formed under the substrate supporting pin 31. A variety of means, such as a rotary motor, for controlling the rotary movement of the substrate support 130 can be used as the rotational actuator 34.

Next, the vertical movement of the substrate support 130 for loading or unloading the substrate 131 will be explained. As the substrate support 130 and the heating plate 160, which are connected to the vertical actuator 33, move down before and after a deposition process, the reaction chamber wall 120 and the substrate support 130 are separated from each other and the reaction chamber is therefore opened. Thus, the substrate 131 can be loaded inside the reaction chamber or unloaded outside the reaction chamber. Hereupon, the substrate supporting pin 31 and the supporting pin cover 32 are separated from the substrate support 130 and support the substrate 131.

During the deposition process, as shown in FIG. 1, the substrate supporting pin 31 is located within the supporting pinhole formed in the substrate support 130, and the supporting pin cover 32 is located in the hole of the substrate support 130 and placed on top of the substrate supporting pin 31. The surface of the supporting pin cover 32 is almost the same height as the surface of the substrate support 130 such that no empty space is formed on the back side of the substrate 131 loaded on the substrate support 130.

As such, the substrate supporting pin 31 and the supporting pin cover 32 rise or fall by the vertical movement of the supporting plate 101, and allow the substrate 131 to be unloaded from the substrate support 130 or loaded on the substrate support 130.

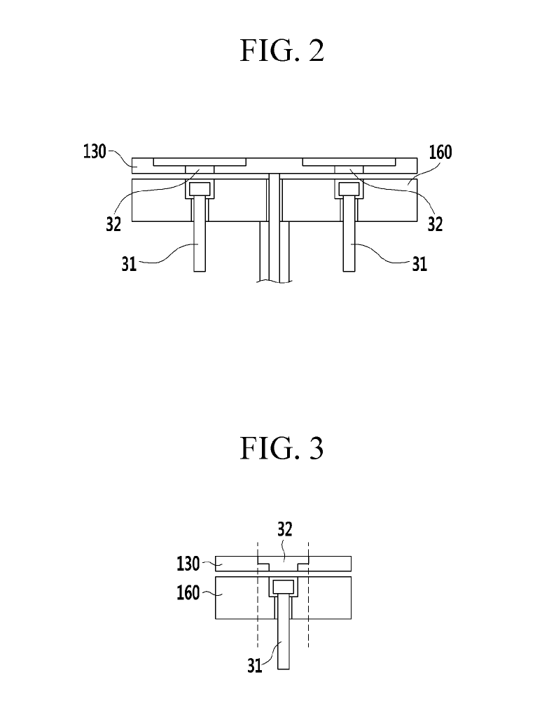

Now, the substrate supporting pin 31 and supporting pin cover 32 of the deposition apparatus according to the exemplary embodiment of the present invention will be explained with reference to FIG. 2. FIG. 2 is a cross-sectional view showing part of a deposition apparatus according to one exemplary embodiment of the present invention.

Referring to FIG. 2, the substrate supporting pin 31 is inserted into a supporting pin hole which penetrates the substrate support 130 and the heating plate 160 located under the substrate support 130. During the deposition process, the substrate supporting pin 31 is arranged lower than the substrate support 130, and the supporting pin cover 32 is arranged on top of the substrate supporting pin 31. The supporting pin cover 32 is made of a highly heat-conductive material. For example, the supporting pin cover 32 may be made of aluminum, titanium, nickel, or the same material as the substrate support 130.

During the deposition process, the upper surface of the supporting pin cover 32 is the same height as the upper surface of the substrate support 130. Thus, no empty space is formed between the bottom surface of the substrate 131 where the substrate support 130 is loaded, the substrate support 130, and the supporting pin cover 32.

Consequently, there is no space in which a reacting gas can move to the back side of the substrate 131, and this avoids unnecessary deposition, thus preventing contaminating particles from being generated by the unnecessary deposition of the reacting gas on the backside of the substrate. Moreover, parasitic plasma generated in the space at the back side of the substrate 131 can be prevented, thereby avoiding unnecessary deposition there.

As the supporting pin cover 32 is made of a highly heat-conductive material, the heat from the heating plate 160 can be properly transferred to the substrate 131. Accordingly, a temperature difference between the area with the supporting pin hole formed in the substrate support 130 and other areas can be avoided.

Therefore, the surface temperature of the substrate 131 loaded on the substrate support 130 can be maintained constant over the entire surface, and this can prevent local non-uniformity in deposition rate and thin film characteristics, caused by the temperature difference, and increase the uniformity of a thin film to be formed on the substrate 131.

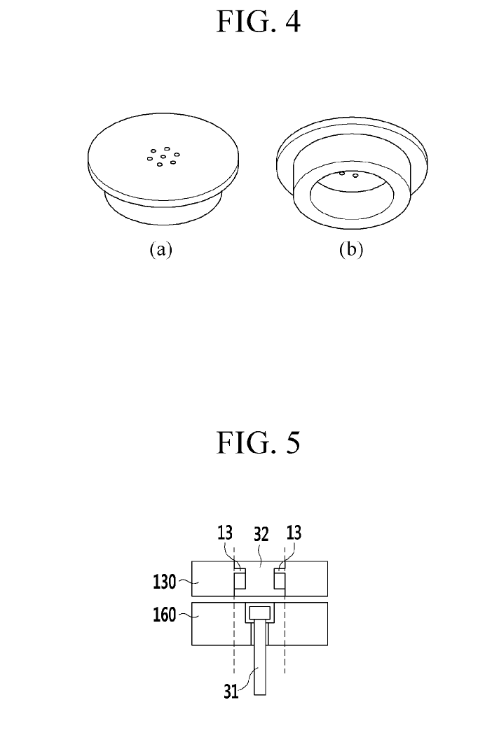

Next, a substrate supporting pin and a supporting pin cover according to an exemplary embodiment of the present invention will be explained with reference to FIG. 3 and FIG. 4. FIG. 3 and FIG. 4 are views showing a substrate supporting pin cover of a deposition apparatus according to an exemplary embodiment of the present invention.

Referring to FIG. 3 and FIG. 4, the substrate supporting pin 31 has an upper surface having a relatively large cross-sectional area and a lower surface having a relatively small cross-sectional area. The substrate supporting pin 32 includes a lower surface where a recess for covering the upper surface of the substrate supporting pin 31 is formed, and an upper surface which has the same area as the supporting pin hole of the substrate support 130. According to this structure, if the substrate 131 is loaded on the substrate support 130, the upper part of the supporting pin hole of the substrate support 130 is blocked by the supporting pin cover 32. Accordingly, no empty space is formed on the back side of the substrate 131 loaded on the substrate support 130.

Referring to FIG. 4, a plurality of through holes is formed in the upper surface of the supporting pin cover 32. As shown in (a) and (b) of FIG. 4, the through holes provide passages through which process gases which may be flowed into during the process or inactive purge gases pass, thereby preventing the substrate supporting pin 31 and the supporting pin cover 32 from being separated during the process or during the loading or unloading of the substrate 131 and allowing them to be firmly attached to each other.

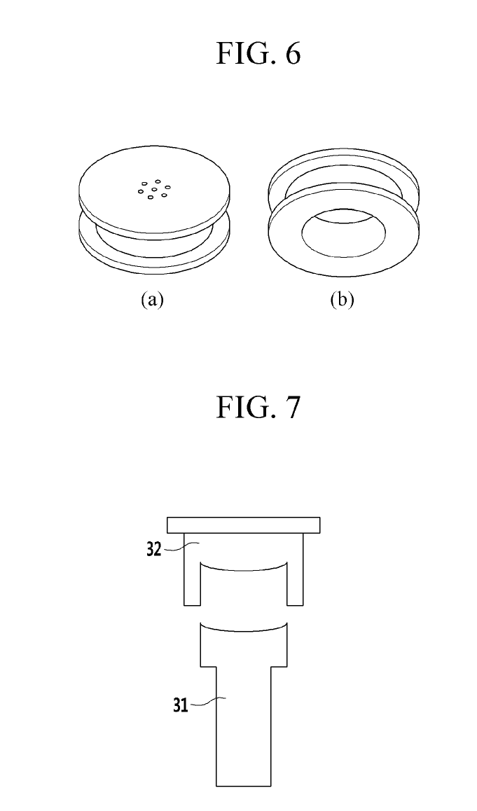

Next, a substrate supporting pin and a supporting pin cover according to an exemplary embodiment of the present invention will be explained with reference to FIG. 5 and FIG. 6. FIG. 5 and FIG. 6 are views showing a substrate supporting pin cover of a deposition apparatus according to another exemplary embodiment of the present invention.

Referring to FIG. 5 and FIG. 6, the substrate supporting pin 31 has an upper surface having a relatively large cross-sectional area and a lower surface having a relatively small cross-sectional area. The substrate supporting pin cover 32 includes a lower surface where a recess for covering the upper surface of the substrate supporting pin 31 is formed and which has the same area as a supporting pin hole of the substrate support 130, and an upper surface which has the same area as the supporting pin hole of the substrate support 130. The upper and lower surfaces of the supporting pin cover 32 are coupled together through a central part having a smaller area than the supporting pin hole. According to this structure, if the substrate 131 is loaded on the substrate support 130, the upper part of the supporting pin hole of the substrate support 130 is blocked by the supporting pin cover 32. Accordingly, no empty space is formed on the back side of the substrate 131 loaded on the substrate support 130.

A projecting portion 13 is formed on the substrate support 130 as shown in FIG. 5. The projecting portion 13 is located within the supporting pin hole. The projecting portion 13 of the substrate support 130 is arranged corresponding in position to the central part having a small area between the upper surface and the lower surface, and therefore serves to fix the supporting pin cover 32 so as to not deviate outward. Specifically, when the substrate supporting pin 31 and the supporting pin cover 32 move upward, the projecting portion 13 of the substrate support 130 supports the lower surface of the supporting pin cover 32 to prevent the supporting pin cover 32 from moving up and deviating unnecessarily. Accordingly, the substrate supporting pin 31 located under the supporting pin cover 32 is also kept from moving upward and deviating unnecessarily. Similarly, even if the supporting pin 32 moves down, the projecting portion 13 of the substrate support 130 supports the upper surface of the supporting pin cover 32, thereby preventing the supporting pin cover 32 from moving downward unnecessarily. The projecting portion 13 may take the form of a plate-like circle so as to surround the supporting pin cover 32 in a circle, or the form of a plurality of protuberances located around the supporting pin cover 32 so as to partially support the supporting pin cover 32.

Referring to FIG. 6, a plurality of through holes is formed in the upper surface of the supporting pin cover 32. The through holes provide passages through which process gases which may be flowed into during the process or inactive purge gases pass.

Next, various examples of a substrate supporting pin and a substrate supporting pin cover of a deposition apparatus according to an exemplary embodiment of the present invention will be described with reference to FIGS. 7 to 12. FIG. 7 to FIG. 12 are views showing examples of a substrate supporting pin and a substrate supporting pin cover of a deposition apparatus according to exemplary embodiments of the present invention.

Referring to FIG. 7, the substrate supporting pin 31 has an upper surface having a relatively large cross-sectional area and a lower surface having a relatively small cross-sectional area. Also, the upper surface of the substrate supporting pin 31 is concave.

The substrate supporting pin cover 32 includes a lower surface where a recess for covering the upper surface of the substrate supporting pin 31 is formed and which has the same area as a supporting pin hole of the substrate support 130, and an upper surface which has the same area as the supporting pin hole of the substrate support 130. The recess of the supporting pin cover 32 is convex so as to engage with the concavity formed on the upper surface of the substrate supporting pin 31. With this configuration, the substrate supporting pin 31 and the supporting pin cover 32 can be closely coupled together before and after the deposition process, while the substrate supporting pin 31 and the supporting pin cover 32 are supporting the substrate 131.

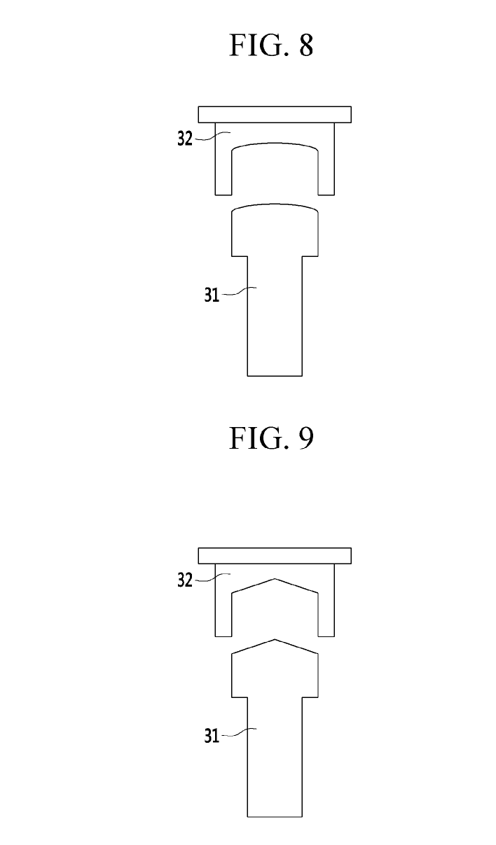

Referring to FIG. 8, the substrate supporting pin 31 has an upper surface having a relatively large cross-sectional area and a lower surface having a relatively small cross-sectional area. Also, the upper surface of the substrate supporting pin 31 is convex.

The substrate supporting pin cover 32 includes a lower surface where a recess for covering the upper surface of the substrate supporting pin 31 is formed and which has the same area as a supporting pin hole of the substrate support 130, and an upper surface which has the same area as the supporting pin hole of the substrate support 130. The recess of the supporting pin cover 32 is concave so as to engage with the convexity formed on the upper surface of the substrate supporting pin 31. With this configuration, the substrate supporting pin 31 and the supporting pin cover 32 can be closely coupled together before and after the deposition process, while the substrate supporting pin 31 and the supporting pin cover 32 are supporting the substrate 131.

Referring to FIG. 9, the substrate supporting pin 31 has an upper surface having a relatively large cross-sectional area and a lower surface having a relatively small cross-sectional area. Also, the center of the upper surface of the substrate supporting pin 31 is raised and has a triangular pyramid shape.

The substrate supporting pin cover 32 includes a lower surface where a recess for covering the upper surface of the substrate supporting pin 31 is formed and which has the same area as a supporting pin hole of the substrate support 130, and an upper surface which has the same area as the supporting pin hole of the substrate support 130. The recess of the supporting pin cover 32 is concave in the shape of a triangular pyramid so as to engage with the triangular pyramid-like convexity formed on the upper surface of the substrate supporting pin 31.

With this configuration, the substrate supporting pin 31 and the supporting pin cover 32 can be closely coupled together before and after the deposition process, while the substrate supporting pin 31 and the supporting pin cover 32 are supporting the substrate 131.

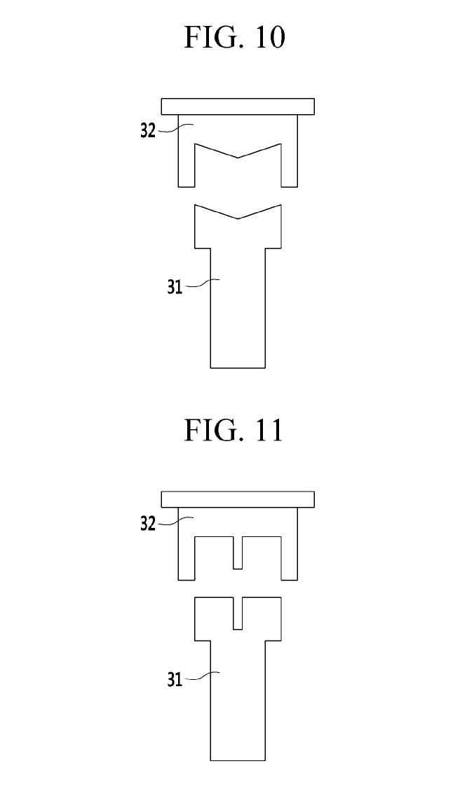

Referring to FIG. 10, the substrate supporting pin 31 has an upper surface having a relatively large cross-sectional area and a lower surface having a relatively small cross-sectional area. Also, the center of the upper surface of the substrate supporting pin 31 is lowered at a given angle.

The substrate supporting pin cover 32 includes a lower surface where a recess for covering the upper surface of the substrate supporting pin 31 is formed and which has the same area as a supporting pin hole of the substrate support 130, and an upper surface which has the same area as the supporting pin hole of the substrate support 130. The center of the recess of the supporting pin cover 32 projects at a given angle so as to engage with the shape of the upper surface of the substrate supporting pin 31.

With this configuration, the substrate supporting pin 31 and the supporting pin cover 32 can be closely coupled together before and after the deposition process, while the substrate supporting pin 31 and the supporting pin cover 32 are supporting the substrate 131.

Referring to FIG. 11, the substrate supporting pin 31 has an upper surface having a relatively large cross-sectional area and a lower surface having a relatively small cross-sectional area. Also, a coupling slot is formed at the center of the upper surface of the substrate supporting pin 31.

The substrate supporting pin cover 32 includes a lower surface where a recess for covering the upper surface of the substrate supporting pin 31 is formed and which has the same area as a supporting pin hole of the substrate support 130, and an upper surface which has the same area as the supporting pin hole of the substrate support 130. The recess of the supporting pin cover 32 has a coupling projection that is to be inserted into the coupling slot formed in the upper surface of the substrate supporting pin 31.

With this configuration, the substrate supporting pin 31 and the supporting pin cover 32 can be closely coupled together before and after the deposition process, while the substrate supporting pin 31 and the supporting pin cover 32 are supporting the substrate 131.

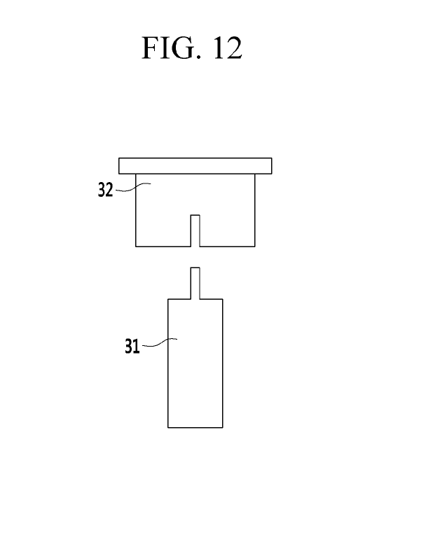

Referring to FIG. 12, the substrate supporting pin 31 has a lower surface having a constant cross-sectional area and a coupling projection that projects at the center of the lower surface.

The substrate supporting pin cover 32 includes a lower surface which has the same area as a supporting pin hole of the substrate support 130 and an upper surface which has the same area as the supporting pin hole of the substrate support 130. A coupling slot for inserting the coupling projection of the substrate supporting pin 31 is formed in the lower surface of the supporting pin cover 32.

With this configuration, the substrate supporting pin 31 and the supporting pin cover 32 can be closely coupled together before and after the deposition process, while the substrate supporting pin 31 and the supporting pin cover 32 are supporting the substrate 131.

The configuration and arrangement of the substrate supporting pin, substrate supporting pin protection member, and substrate support pin guide member of the deposition apparatus according to the above-explained exemplary embodiments are merely examples for illustrative purposes, and the present invention is not limited to these exemplary embodiments and may be modified in various ways.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A deposition apparatus comprising:
a substrate support;
a substrate supporting pin inserted into a hole formed in the substrate support;
a supporting plate supporting the substrate supporting pin; and
a supporting pin cover arranged on top of the substrate supporting pin within the hole of the substrate support.

2. The deposition apparatus of claim 1, wherein an upper surface of the supporting pin cover is almost the same height as an upper surface of the supporting plate.

3. The deposition apparatus of claim 2, wherein the upper surface of the supporting pin cover has almost the same cross-sectional area as the hole.

4. The deposition apparatus of claim 3, wherein the supporting pin cover comprises a lower body located under the upper surface of the supporting pin cover and shaped to form an insertion hole, and the insertion hole has almost the same cross-sectional area as the substrate supporting pin.

5. The deposition apparatus of claim 4, wherein:
an upper surface of the substrate supporting pin is concave or convex, and
the insertion hole of the supporting pin cover is convex or concave so as to engage with a concavity or convexity on the upper surface of the substrate supporting pin.

6. The deposition apparatus of claim 4, wherein:
a coupling slot having a smaller cross-sectional area than the substrate supporting pin is formed in the upper surface of the substrate supporting pin, and
a coupling projection having almost the same cross-sectional area as the coupling slot is formed on a lower surface of the supporting pin cover.

7. The deposition apparatus of claim 4, wherein:
the substrate support comprises a projecting portion, and
the projecting portion takes the form of a plate-like circle surrounding the supporting pin cover in a circle or the form of a plurality of protuberances arranged around the supporting pin cover.

8. The deposition apparatus of claim 3, wherein:
a coupling projection having a smaller cross-sectional area than the substrate supporting pin is formed on an upper surface of the substrate supporting pin, and
a coupling slot having almost the same cross-sectional area as the coupling projection is formed in a lower surface of the supporting pin cover.

9. The deposition apparatus of claim 3, wherein the supporting pin cover comprises a lower surface having almost the same cross-sectional area as the hole.

10. The deposition apparatus of claim 3, wherein a plurality of through holes are formed in the upper surface of the supporting pin cover.

11. The deposition apparatus of claim 3, wherein:
the substrate support comprises a projecting portion, and
the projecting portion takes the form of a plate-like circle surrounding the supporting pin cover in a circle or the form of a plurality of protuberances arranged around the supporting pin cover.

12. The deposition apparatus of claim 2, wherein the supporting pin cover comprises a lower body located under the upper surface of the supporting pin cover and shaped to form an insertion hole, and the insertion hole has almost the same cross-sectional area as the substrate supporting pin.

13. The deposition apparatus of claim 12, wherein:
an upper surface of the substrate supporting pin is concave or convex, and
the insertion hole of the supporting pin cover is convex or concave so as to engage with a concavity or convexity on the upper surface of the substrate supporting pin.

14. The deposition apparatus of claim 12, wherein:
a coupling slot having a smaller cross-sectional area than the substrate supporting pin is formed in an upper surface of the substrate supporting pin, and
a coupling projection having almost the same cross-sectional area as the coupling slot is formed on a lower surface of the supporting pin cover.

15. The deposition apparatus of claim 2, wherein:
a coupling projection having a smaller cross-sectional area than the substrate supporting pin is formed on an upper surface of the substrate supporting pin, and
a coupling slot having almost the same cross-sectional area as the coupling projection is formed in a lower surface of the supporting pin cover.

16. The deposition apparatus of claim 2, wherein the supporting pin cover comprises a lower surface having almost the same cross-sectional area as the hole.

17. The deposition apparatus of claim 2, wherein a plurality of through holes are formed in the upper surface of the supporting pin cover.

18. The deposition apparatus of claim 2, wherein:
the substrate support comprises a projecting portion, and
the projecting portion takes the form of a plate-like circle surrounding the supporting pin cover in a circle or the form of a plurality of protuberances arranged around the supporting pin cover.
